(19) United States
(12) Patent Application Publication
(10) Pub. No.: US 2013/0155654 A1
(43) Pub. Date: Jun. 20, 2013

(54) DISPLAY DEVICE AND RESILIENT FRAME THEREOF

(71) Applicant: AU OPTRONICS CORP., Hsin-chu (TW)

(72) Inventors: Shu-Ling LIN, Hsin-Chu (TW); Ping LEE, Hsin-Chu (TW); Chi-Yung LIN, Hsin-Chu (TW); Te-Hen LO, Hsin-Chu (TW); Chia-Hung CHEN, Hsin-Chu (TW); Hao-Liang CHAO, Hsin-Chu (TW); Wen-Chang SONG, Hsin-Chu (TW)

(73) Assignee: AU OPTRONICS CORP., Hsin-Chu (TW)

(21) Appl. No.: 13/664,889

(22) Filed: Oct. 31, 2012

(30) Foreign Application Priority Data
Dec. 15, 2011 (TW) 100146622
Sep. 24, 2012 (TW) 101135005

(51) Int. Cl. H05K 7/14; H05K 7/04; A47B 81/06; G09F 13/04; H05K 7/18

(52) U.S. Cl. 362/97.1; 361/747; 312/223.2; 312/7.2; 312/223.6

(57) ABSTRACT

A display device includes a display module and a frame. The frame is made of a resilient material. The frame includes a sidewall, a first securing portion and a second securing portion. The first securing portion extends from a top end of the sidewall. The second securing portion extends from a bottom end of the sidewall, and the second securing portion is opposite to the first securing portion. A containing space enclosed by the first securing portion, the second securing portion and the sidewall is configured to contain sides of the display module. The frame secures the display module through resilience of the resilient material.

### TECHNICAL FIELD

The present invention relates to display devices and its frames, and more particularly to a display device and a resilient frame of the display device.

### BACKGROUND

With the booming development of high technology electronic information industry, consumer electronics have become necessaries of daily life. Due to the advantages of compact size, light weight and low radiation, liquid crystal display device has become the mainstream of display products.

FIG. 1 is a schematic, cross sectional view of a conventional liquid crystal display device. Referring to FIG. 1, the conventional liquid crystal display device 100 includes a liquid crystal display panel 10, a backlight module 11, a front frame 12, a protection cover 13 and a driving circuit board 14. The backlight module 11 includes a back plate 114 and a supporting bracket 115. The liquid crystal display panel 10 is disposed on the supporting bracket 115. The backlight module 11 is disposed under the liquid crystal display panel 10 and provides light for the liquid crystal display panel 10. The driving circuit board 14 is electrically connected to the liquid crystal display panel 10 by a flexible printed circuit board 15. The front frame 12 covers a side of a display surface of the liquid crystal display panel 10 and is secured to the supporting bracket 115. The protection cover 13 covers the driving circuit board 14 from a side of the front frame 12.

In the conventional liquid crystal display device 100, the front frame 12 is usually made of metallic material and needs to be screwed or clasped to the supporting bracket 115. Therefore, a plurality of mounting holes for screwing or a plurality of clasping grooves for clasping is needed to be formed on the front frame 12. Furthermore, the protection cover 13 is needed to be secured to the driving circuit board 14 to protect the driving circuit board 14. However, forming the mounting holes and the clasping grooves on the front frame 12 need a number of punching processes, thereby increasing the manufacturing cost and will generate a plenty of scraps. Moreover, a plurality of metallic filings will be generated when screwing the front frame 12 to the supporting bracket 115. If the metallic filings could not be completely removed, the quality of the liquid crystal display device 100 will be affected. In addition, the disassembly of the liquid crystal display device assembled by screwing or clasping manner will need additional tools, besides for low speed of disassembly, the damage possibility of the liquid crystal display panel 10, the backlight module 11 and the driving circuit board 14 will be increased.

### SUMMARY

A purpose of the present invention is to provide a display device, which includes a frame made of resilient material, for securing a display module by resilience of the resilient material.

Another purpose of the present invention is to provide a resilient frame, which is used for securing a backlight unit, a display panel and a driving circuit board of a display module by the resilience of the resilient frame.

In order to achieve at least of the above-mentioned advantages, the present invention provides a display device including a display module and a frame. The frame is made of a resilient material. The frame includes a sidewall, a first securing portion and a second securing portion. The first securing portion extends from a top end of the sidewall. The second securing portion extends from a bottom end of the sidewall, and opposite to the first securing portion. A containing space enclosed by the second securing portion, the first securing portion and the sidewall is configured to contain sides of the display module. The frame secures the display module through resilience of the resilient material.

In order to achieve at least of the above-mentioned advantages, the present invention further provides a resilient frame configured for securing a display module. The display module includes a display panel disposed on a backlight unit and a driving circuit board electrically connected to the display panel. The backlight unit is disposed between the display panel and the driving circuit board. The resilient frame includes a sidewall, a first securing portion extending from a top end of the sidewall, and a second securing portion extending from a bottom end of the sidewall and opposite to the first securing portion. A containing space is enclosed by the first securing portion, the second securing portion and the sidewall and configured for containing sides of the backlight unit and sides of the display panel. The backlight unit, the display panel and the driving circuit board are secured by the first securing portion, the second securing portion and the sidewall through resilience of a resilient material.

In the present invention, the frame is made of resilient material. The frame includes the sidewall, the first and the second securing portions respectively extending from the top end and the bottom end of the sidewall, and the second securing portion is opposite to the first securing portion. Under this foregoing structure construction, sides of the display module could be contained in the containing space enclosed by the second securing portion, the first securing portion and the sidewall. Meanwhile, the display module could be secured by the frame through resilience of the resilient material of the frame. Therefore, the present invention solves damaging problems brought by securing the conventional front frame through screwing or clasping manner and inconvenience problems of disassembling the display device when is needed to rework. The present invention further provides a buffer force for protecting the display device.

### BRIEF DESCRIPTION OF THE DRAWINGS

The disclosure will become more readily apparent to those ordinarily skilled in the art after reviewing the following detailed description and accompanying drawings.

FIG. 1 shows a cross sectional view of a conventional liquid crystal display device.

FIG. 2 shows a schematic, cross sectional view of a display device according to an embodiment of the present invention.

FIG. 3 shows a schematic, three dimensional view of a frame of the display device.

FIG. 4 shows an enlarged view of a circled portion IV of the frame.

FIG. 5 shows a schematic, three dimensional view of another frame, a backlight unit and a housing of an electronic product.

FIG. 6 shows a cross sectional view of a frame according to another embodiment of the present invention.

FIG. 7 shows a schematic, three dimensional view of an embodiment of a protruding portion of a first securing portion of the frame.

FIG. 8 shows a schematic, three dimensional view of another embodiment of the protruding portion of the first securing portion of the frame.

FIGS. 9A and 9B show cross sectional views of a frame according to further embodiments of the present invention.

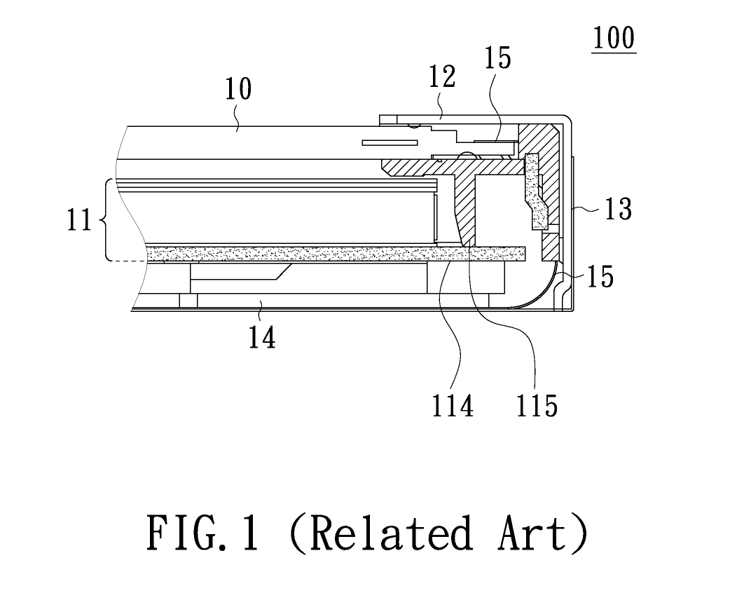

### DETAILED DESCRIPTION OF EMBODIMENTS

The disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed.

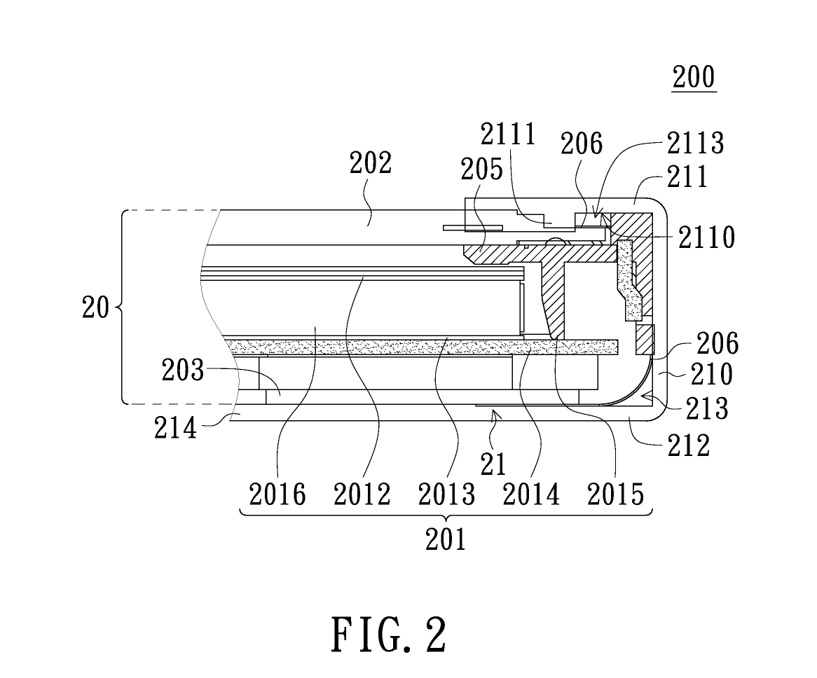

FIG. 2 shows a schematic, cross sectional view of a display device according to an embodiment of the present invention. According to FIG. 2, the display device 200 of the present embodiment includes a display module 20 and a frame 21. The frame 21 is made of a resilient material, such as silicone rubber, rubber, electroconductive rubber, or rubber with conductive particles. It should be noted that, if the frame 21 is made of electroconductive rubber or rubber with conductive particles, the frame 21 may have EMI (Electro-Magnetic Interference) shielding or ESD (electrostatic discharge) protection capability. The frame 21 includes a sidewall 210, a first securing portion 211 and a second securing portion 212. The first securing portion 211 extends from a top end of the sidewall 210. The second securing portion 212 extends from a bottom end of the sidewall 210 and opposite to the first securing portion 211. A containing space 213 is enclosed by the first securing portion 211, the second securing portion 212 and the sidewall 210. When the display module 20 is assembled to the frame 21, sides of the display module 20 is contained by the containing space 213 of the frame 21, meanwhile, the display module 20 is secured by the first securing portion 211 and the second securing portion 212 of the frame 21 through resilience of the resilient material of the frame 21. The detailed structures of the display device 200 of the present embodiment are described hereinafter.

As shown in FIG. 2, the display module 20 of the present embodiment, for example, includes a backlight unit 201, a display panel 202 and a driving circuit board 203. The backlight unit 201 is disposed between the first securing portion 211 and the second securing portion 212. The display panel 202 is disposed between the backlight unit 201 and the first securing portion 211. The backlight unit 201, for example, includes a back plate 2014 and a supporting bracket 2015. The supporting bracket 2015 is disposed between the back plate 2014 and the display panel 202, and the supporting bracket 2015 surrounds the display panel 202. Furthermore, the supporting bracket 2015 includes a supporting portion 205 for supporting the display panel 202. The driving circuit board 203 is electrically connected to the display panel 202 by a flexible printed circuit board 206, and the driving circuit board 203 is disposed between the backlight unit 201 and the second securing portion 212. More concretely, the driving circuit board 203 is, for example, disposed between the back plate 2014 and the second securing portion 212. The driving circuit board 203 may have an insulation pad for preventing short circuits formed between electronic components on the driving circuit board 203 and the back plate 2014. It should be noted that, in FIG. 2, the flexible printed circuit board 206 is partially shielded by the supporting bracket 2015, and therefore is discontinuous as seen in FIG. 2. Furthermore, the backlight unit 201, for example, includes an optical sheet 2012, a reflector 2013 and a light guide plate 2016. The optical sheet 2012 may be light enhancing sheet, diffusion sheet, uniform sheet, a composite optical sheet or a combination of the forgoing sheets. If the backlight unit 201 is a direct type backlight unit, the light guide plate 2016 may be omitted.

The display panel 202 of the forgoing display module 20 is a nonselfluminous display panel such as a liquid crystal display panel. In another embodiment, if the display panel 202 of the display module 20 is a self-luminous display panel such as an organic light emitting display, the display module 20 is no need to include the backlight unit 201. No matter the display module 20 is the nonselfluminous display panel or the self-luminous display panel, the frame 21 could still secure the display module 20.

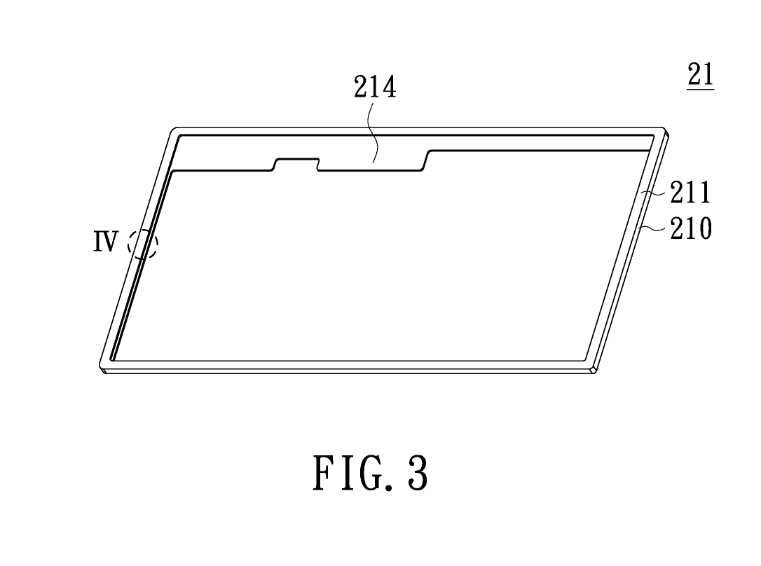

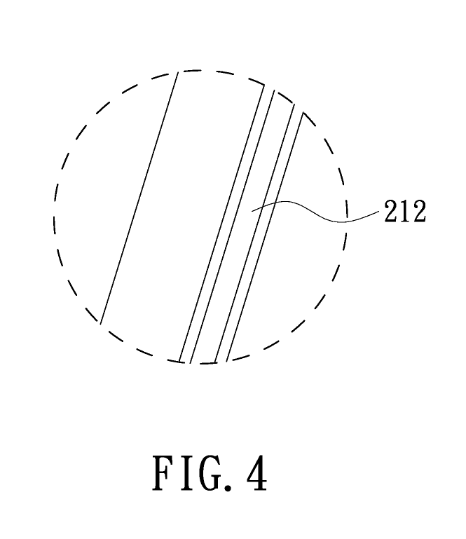

FIG. 3 shows a schematic, three dimensional view of the frame of the display device, and FIG. 4 shows an enlarged view of a circled portion IV of the frame. Referring to FIGS. 2 to 4, the second securing portion 212 of the frame 21, for example, includes a board securing portion 214. The board securing portion 214 extends from the second securing portion 212 and the board securing portion 214 corresponds to the driving circuit board 203. When the sides of the display module 20 is contained in the containing space 213 of the frame 21, the first securing portion 211 and the second securing portion 212 secures the display module 20, and the board securing portion 214 of the second securing portion 212 covers and secures the driving circuit board 203 through the resilience of the resilient material, preventing the driving circuit board 203 from exposing out from the frame 21 and thereby protecting the driving circuit board 203. It should be noted that, FIG. 3 merely shows an embodiment but not limit the configuration of the board securing portion 214.

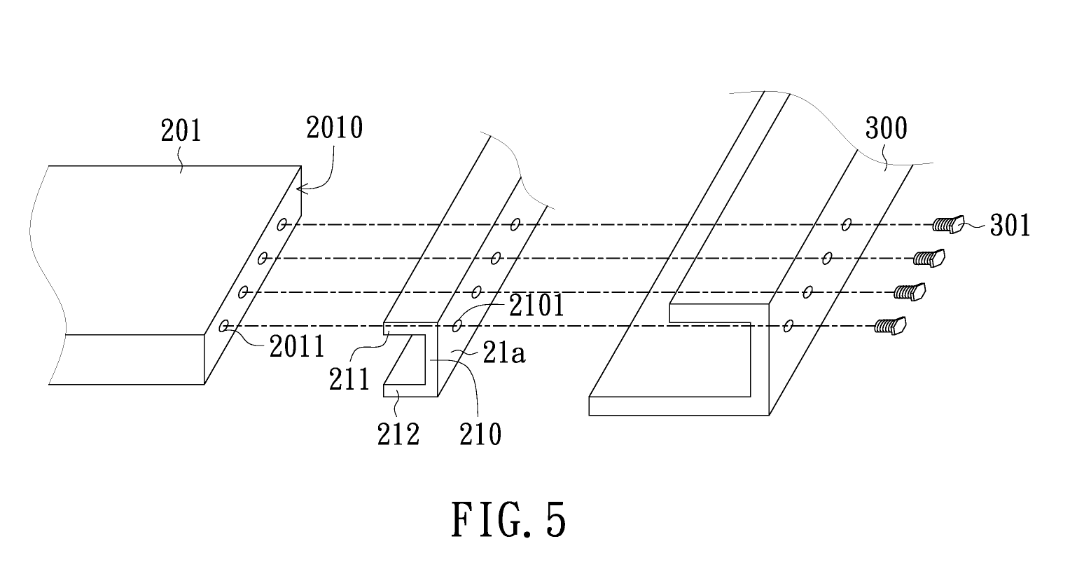

FIG. 5 shows a schematic, three dimensional view of the frame, the backlight unit and a housing. In FIG. 5, only a portion of the frame 21a is shown and the entire structure of the frame could refer to FIG. 3. Furthermore, FIG. 5 only shows a schematic view but not a practical view of the backlight unit 201. Referring to FIG. 5, when the display device 200 is applied to an electronic product, the display device 200 needs to be assembled to a housing 300 of the electronic product, and the frame 21a is disposed between the housing 300 of the electronic product and the display module 20. Therefore, a plurality of mounting holes 2011 should be defined in a side surface 2010 (a side surface of the back plate 2014 or a side surface of the supporting bracket 2015 of FIG. 2) of the backlight unit 201 of the display module 20. The mounting holes 2011 are used for receiving a plurality of securing elements 301 such as screws or clasping elements to secure the backlight unit 201 to the housing 300. In the present embodiment, a plurality of through holes 2101 may be defined in the frame 21a such as in the sidewall 210 or in the second securing portion 212. The positions of the through holes 2101 are disposed correspond to the mounting holes 2011 of the side surface 2010 of the backlight unit 201, such that the securing elements 301 could pass through the through holes 2101 and be fixed in the mounting holes 2011.

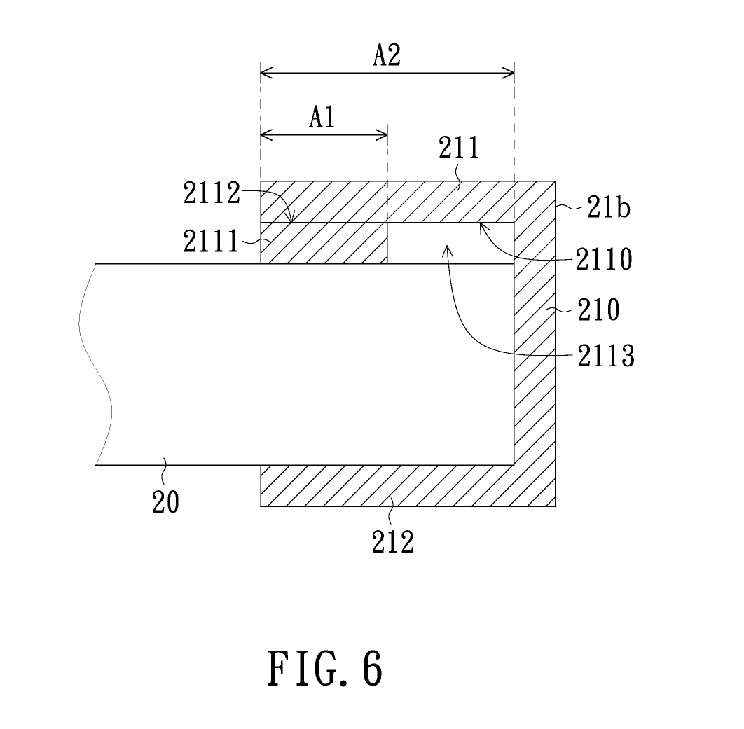

FIG. 6 shows a schematic view of a frame according to another embodiment of the present invention. Referring to FIG. 6, the first securing portion 211 of the frame 21b includes a protruding portion 2111 formed on an inner surface 2110 of the first securing portion 211. A height of the protruding portion 2111 is, for example, in a range from 0.2 cm to 0.3 cm. When the frame 21b is assembled to the display module 20 (the display module 20 of the present embodiment, for example, has the same structure as the display module of FIG. 2), the protruding portion 2111 on the inner surface 2110 of the first securing portion 211 contacts the display module 20. An area A1 of a connecting surface 2112 of the protruding portion 2111 connected to the first securing portion 211 is smaller than an area A2 of the inner surface 2110 of the first securing portion 211, such that a buffer space 2113 is formed between the first securing portion 211 and the display module 20 when the protruding portion 2111 contacts the display module 20. Due to the frame 21b is made of resilient material and the buffer space 2113 formed between the first securing portion 211 and the display module 20, when the display device 200 is impacted by external force or drops off on the ground by accident, the buffer space 2113 could buffer the impact force exerted on the display device 200, and further prevents components of the display module 20 from being damaged by the impact force.

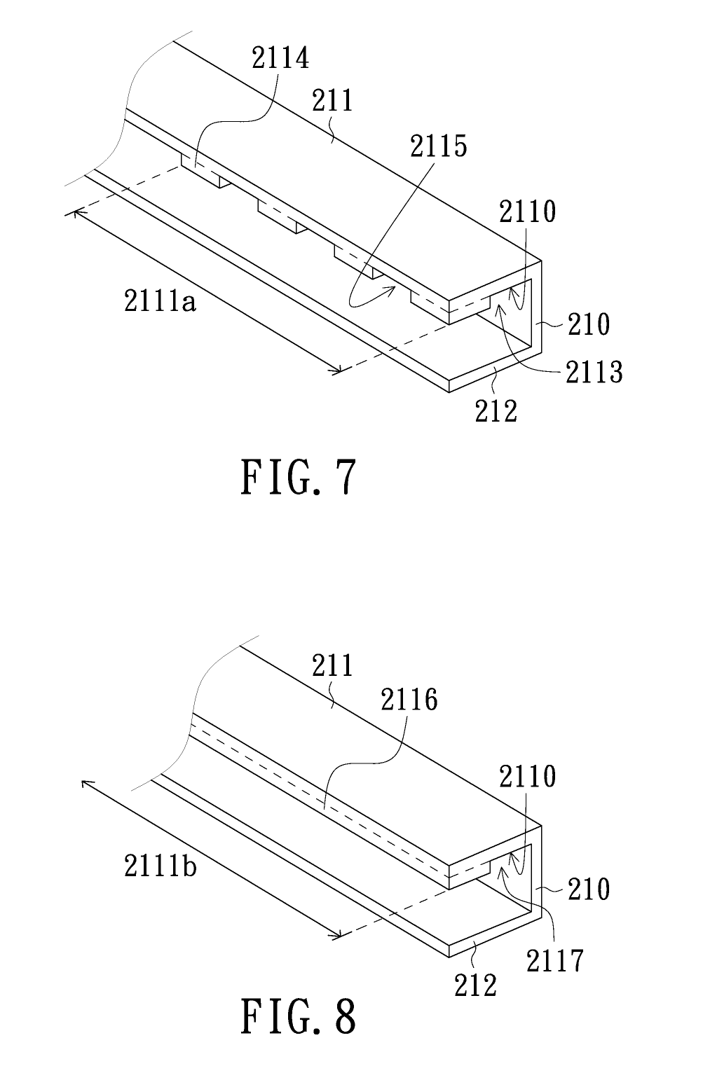

FIG. 7 shows an embodiment of the protruding portion of the first securing portion. Referring to FIG. 7, the protruding portion 2111a of the first securing portion 211 includes a plurality of bumps 2114. The bumps 2114 are, for example, arranged with the same interval on the inner surface 2110 of the first securing portion 211. A gap 2115 is formed between adjacent bumps 2114, and the buffer space 2113 includes the gaps 2115 for effectively decreasing the impact force exerted on the display device 200.

FIG. 8 shows another embodiment of the protruding portion of the first securing portion. Referring to FIG. 8, the protruding portion 2111b of the first securing portion 211 is a protruding strip 2116. The protruding strip 2116 is formed on the inner surface 2110 of the first securing portion 211. The protruding strip 2116 is at a side of the first securing portion 211 opposite to another side of the first securing portion 211 connected to the sidewall 210 and the protruding strip 2116 extends along the side of the first securing portion 211. A gap 2117 is formed between the protruding strip 2116 and the sidewall 210 and the buffer space 2113 includes the gap 2117, for effectively decreasing the impact force exerted on the display device 200. It should be noted that, the embodiments of the protruding portion merely illustrates but not limit the structure of the protruding portion, and the structure of the protruding portion could be changed according to requirements.

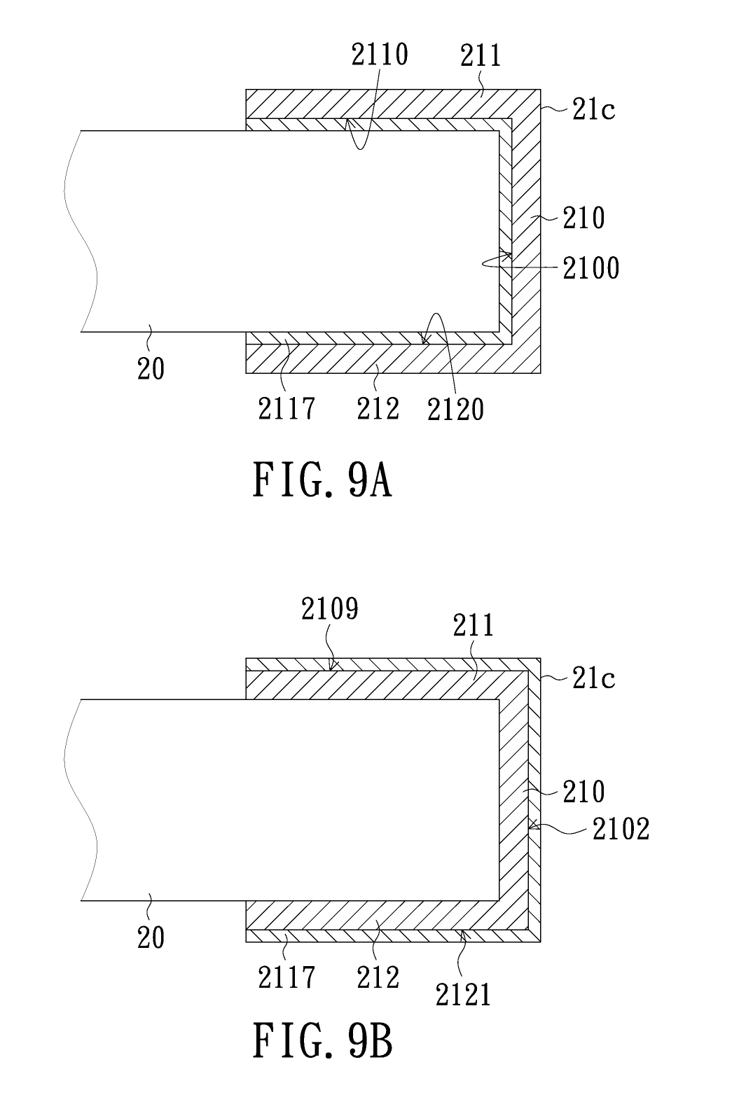

FIGS. 9A and 9B show schematic views of a frame according to further embodiments of the present invention. Referring to FIGS. 9A, the frame 21c of the embodiment includes a conducting layer 2117. The conducting layer 2117 extends along an inner surface 2100 of the sidewall 210, an inner surface 2110 of the first securing portion 211 and an inner surface 2120 of the second securing portion 212, and surrounds a corresponding side of the display module 20. Referring to FIG. 9B, the conducting layer 2117 of the embodiment extends along an outer surface 2102 of the sidewall 210, an outer surface 2109 of the first securing portion 211 and an outer surface 2121 of the second securing portion 212. The conducting layer 2117 for example but not limited to include a plurality of conductive particles or a metallic film layer. It should be noted that, if the frame 21c has the conducting layer 2117, the frame 21c may have EMI (Electro-Magnetic Interference) shielding or ESD (electrostatic discharge) protection capability.

As mentioned above, in the present invention, the display module is secured by the frame which is made of resilient material. That is to say, a size of the frame is smaller than a size of the display module before deformation, the frame is stretched to contain the display module, and the display module is secured to the frame by resilience of the resilient material. During assembly of the frame and the display module, there is no problems brought by securing the conventional frame through screwing or clasping manner, and the display device of the present invention is easily to be assembled or disassembled. Furthermore, the frame could buffer the impact force exerted on the display device. Therefore, the present invention improves the short comings of the related art.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A display device comprising:
a display module; and
a frame made of a resilient material, the frame comprising:
a sidewall;
a first securing portion extending from a top end of the sidewall; and
a second securing portion extending from a bottom end of the sidewall and opposite to the first securing portion, wherein a containing space is enclosed by the first securing portion, the second securing portion and the sidewall configured for containing sides of the display module, the display module is secured by the frame through resilience of the resilient material.

2. The display device according to claim 1, wherein the display module comprises:
a backlight unit disposed between the first securing portion and the second securing portion; and
a display panel disposed between the backlight unit and the first securing portion.

3. The display device according to claim 2, wherein the backlight unit comprises:
a back plate; and
a supporting bracket disposed between the back plate and the display panel, surrounding the display panel and comprising a supporting portion for supporting the display panel.

4. The display device according to claim 2, wherein the display module further comprises a driving circuit board electrically connected to the display panel and disposed between the backlight unit and the second securing portion.

5. The display device according to claim 4, wherein the second securing portion further comprises a board securing portion extending from the second securing portion and corresponding to the driving circuit board, when the sides of the display module is contained in the containing space of the frame, the board securing portion of the second securing portion covers and secures the driving circuit board through resilience of the resilient material.

6. The display device according to claim 2, wherein a side surface of the backlight unit has a plurality of mounting holes, and the frame has a plurality of through holes corresponding to the mounting holes of the side surface of the backlight unit, and the mounting holes are provided for assembling the backlight unit to a housing.

7. The display device according to claim 1, wherein the resilient material comprises silicone rubber, rubber, electroconductive rubber, or rubber with conductive particles.

8. The display device according to claim 1, wherein a size of the frame is smaller than a size of the display module before deformation, the frame is stretched to contain the display module, and the display module is secured by the frame through resilience of the resilient material.

9. The display device according to claim 1, wherein an inner surface of the first securing portion has a protruding portion configured for contacting with the display module, an area of a connecting surface of the protruding portion connected to the first securing portion is smaller than an area of the inner surface of the first securing portion, and a buffer space is formed between the first securing portion and the display module when the protruding portion contacts the display module.

10. The display device according to claim 9, wherein the protruding portion comprises a plurality of bumps arranged with the same intervals on the inner surface of the first securing portion, a gap is formed between adjacent bumps and the buffer space includes the gaps.

11. The display device according to claim 9, wherein the protruding portion comprises a protruding strip, the protruding strip is formed on the inner surface of the first securing portion and is at a side of the first securing portion opposite to another side of the first securing portion connected to the sidewall and the protruding strip extends along the side, a gap is formed between the protruding strip and the sidewall and the buffer space includes the gap.

12. The display device according to claim 1, wherein the frame includes a conducting layer extending along inner or outer surfaces of the sidewall, the first securing portion and the second securing portion, and surrounds a corresponding side of the display module.

13. The display device according to claim 12, wherein the conducting layer comprises a plurality of conductive particles.

14. A resilient frame for securing a display module, the display module comprises a display panel disposed on a backlight unit and a driving circuit board electrically connected to the display panel, the backlight unit is disposed between the display panel and the driving circuit board, the resilient frame comprising:
a sidewall;
a first securing portion extending from a top end of the sidewall; and
a second securing portion extending from a bottom end of the sidewall and opposite to the first securing portion, wherein a containing space is enclosed by the first securing portion, the second securing portion and the sidewall configured for containing sides of the display module, the display module is secured by the first securing portion, the second securing portion and the sidewall through resilience of a resilient material.

15. The resilient frame according to claim 14, wherein the backlight unit is disposed between the first securing portion and the second securing portion, and the display panel is disposed between the backlight unit and the first securing portion.

16. The resilient frame according to claim 14, wherein the driving circuit board is disposed between the backlight unit and the second securing portion.

17. The resilient frame according to claim 14, wherein the second securing portion further comprises a board securing portion extending from the second securing portion and corresponding to the driving circuit board, when the sides of the display module is contained in the containing space of the resilient frame, the board securing portion of the second securing portion covers and secures the driving circuit board through the resilience of the resilient material.

18. The resilient frame according to claim 14, wherein the resilient material comprises silicone rubber, rubber, electroconductive rubber, or rubber with conductive particles.

19. The resilient frame according to claim 14, wherein a size of the resilient frame is smaller than a size of the display module before deformation, the resilient frame is stretched to contain the display module, and the display module is secured by the resilient frame through resilience of the resilient material.

20. The resilient frame according to claim 14, wherein an inner surface of the first securing portion has a protruding portion configured for contacting with the display module, an area of a connecting surface of the protruding portion connected to the first securing portion is smaller than an area of the inner surface of the first securing portion, and a buffer space is formed between the first securing portion and the display module when the protruding portion contacts the display module.

21. The resilient frame according to claim 20, wherein the protruding portion comprises a plurality of bumps arranged with the same intervals on the inner surface of the first securing portion, a gap is formed between adjacent bumps and the buffer space includes the gaps.

22. The resilient frame according to claim 20, wherein the protruding portion comprises a protruding strip, the protruding strip is formed on the inner surface of the first securing portion and is at a side of the first securing portion opposite to another side of the first securing portion connected to the sidewall and the protruding strip extends along the side, a gap is formed between the protruding strip and the sidewall and the buffer space includes the gap.

23. The resilient frame according to claim 14, wherein a side surface of the backlight unit has a plurality of mounting holes, and the resilient frame has a plurality of through holes corresponding to the mounting holes of the side surface of the backlight unit, and the mounting holes are provided for assembling the backlight unit to a housing.

24. The resilient frame according to claim 14, wherein the resilient frame includes a conducting layer extending along inner or outer surfaces of the sidewall, an the first securing portion and the second securing portion, and surrounds a corresponding side of the display module.

25. The resilient frame according to claim 24, wherein the conducting layer comprises a plurality of conductive particles.
